(19) United States
(12) Patent Application Publication
(10) Pub. No.: US 2008/0179665 A1
(43) Pub. Date: Jul. 31, 2008

(54) Semiconductor Memory Devices and Methods of Forming the Same

(75) Inventors: Jong-Wook Lee, Gyeonggi-do (KR); Yong-Hoon Son, Gyeonggi-do (KR); Si-Young Choi, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/019,046

(22) Filed: Jan. 24, 2008

(30) Foreign Application Priority Data
Jan. 25, 2007 (KR) 2007-08028

(51) Int. Cl. H01L 29/78

(52) U.S. Cl. 257/330; 257/E21.41

(57) ABSTRACT

A memory cell transistor includes a semiconductor substrate having a first impurity region of first conductivity type (e.g., N-type) therein. A U-shaped semiconductor layer having a second impurity region of first conductivity type therein is provided on the first impurity region. A gate insulating layer is provided, which lines a bottom and an inner sidewall of the U-shaped semiconductor layer. A gate electrode is provided on the gate insulating layer. The gate electrode is surrounded by the inner sidewall of the U-shaped semiconductor layer. A word line is provided, which is electrically coupled to the gate electrode, and a bit line is provided, which is electrically coupled to the second impurity region.

### CROSS-REFERENCE TO PRIORITY APPLICATION

This U.S. non-provisional patent application claims priority under 35 U.S.C. § 119 to Korean Patent Application No. 2007-08028, filed Jan. 25, 2007, the entire contents of which are hereby incorporated herein by reference in their entirety.

### FIELD OF THE INVENTION

The present invention relates to semiconductor devices and methods of forming same and, more particularly, to semiconductor memory devices and methods of forming semiconductor memory devices.

### BACKGROUND OF THE INVENTION

Conventional methods of forming integrated circuit memory devices may include techniques to form integrated circuit capacitors that function as data storage elements within respective memory cells. However, as integrated circuit memory devices become more highly integrated in order to achieve higher data capacity, the layout area available for capacitors may decrease. Accordingly, to maintain high data storage reliability, techniques have been developed that enable the formation of capacitors having three-dimensional (e.g., U-shaped) storage electrodes that have a relatively large surface area yet require a relatively small layout footprint. Notwithstanding these techniques to achieve higher data capacities using capacitors having three-dimensional storage electrodes, there continues to be a need for techniques that support still higher data capacities.

### SUMMARY OF THE INVENTION

Embodiments of the present invention include methods of forming memory cell transistors that may be compatible with DRAM architectures and memory cell transistors formed thereby. According to some of these embodiments, a memory cell transistor includes a semiconductor substrate having a first impurity region of first conductivity type (e.g., N-type) therein. A U-shaped semiconductor layer having a second impurity region of first conductivity type therein is also provided on the first impurity region. A gate insulating layer is provided, which lines a bottom and an inner sidewall of the U-shaped semiconductor layer. A gate electrode is provided on the gate insulating layer. The gate electrode is surrounded by the inner sidewall of the U-shaped semiconductor layer. A word line is provided, which is electrically coupled to the gate electrode, and a bit line is provided, which is electrically coupled to the second impurity region.

According to some of these embodiments, the U-shaped semiconductor layer, which may be a monocrystalline silicon region, includes a U-shaped channel region that functions as a data storage region within the transistor. The second impurity region may also be a ring-shaped drain region of the transistor. Furthermore, the first impurity region may function as a source region of the transistor, which electrically contacts a bottom of the U-shaped channel region. The bit line may also include a ring-shaped metal region that surrounds and contacts the ring-shaped drain region.

Additional embodiments of the invention include a memory cell transistor formed on a semiconductor substrate, which has a first impurity region of first conductivity type therein that function as a source region of the memory cell transistor. A cylinder-shaped gate electrode is provided on the first impurity region and a U-shaped gate insulating layer is provided on the first impurity region. This insulating layer lines a bottom and sidewall of the cylinder-shaped gate electrode. A ring-shaped semiconductor layer is also provided, which surrounds the U-shaped gate insulating layer. The ring-shaped semiconductor layer has a first end electrically connected to the first impurity region and a second end that includes a drain region of the transistor. A word line is provided, which is electrically coupled to the gate electrode, and a bit line is provided, which is electrically coupled to the second impurity region.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1A is a top plan view of a semiconductor device in accordance with an embodiment of the present invention.

FIG. 1B and FIG. 1C are cross-sectional views taken along the line 1B-1B′ and the line 1C-1C′ of FIG. 1A, respectively.

FIG. 2A is a top plan view of a semiconductor device in accordance with another embodiment of the present invention.

FIG. 2B and FIG. 2C are cross-sectional views taken along the line 2B-2B′ and the line 2C-2C′ of FIG. 2A, respectively.

FIGS. 3A to 3F are cross-sectional views taken along the line 1B-1B′ of FIG. 1A illustrating a method of forming a semiconductor device in accordance with another embodiment of the present invention.

FIGS. 4A to 4D are cross-sectional views taken along the line 1B-1B′ of FIG. 1A illustrating a method of forming a semiconductor device in accordance with another embodiment of the present invention.

FIGS. 5A to 5H are cross-sectional views taken along the line 1B-1B′ of FIG. 1A illustrating a method of forming a semiconductor device in accordance with another embodiment of the present invention.

FIGS. 6A to 6I are cross-sectional views taken along the line 2B-2B′ of FIG. 2A illustrating a method of forming a semiconductor device in accordance with another embodiment of the present invention

### DETAILED DESCRIPTION OF PREFERRED EMBODIMENTS

Embodiments of the present invention will now be described more fully with reference to the accompanying drawings. This invention may, however, be embodied in many different forms and should not be construed as being limited to the embodiments set force herein. Rather, these embodiments are provided so that this disclosure will be thorough and complete, and will fully convey the scope of the invention to those skilled in the art.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

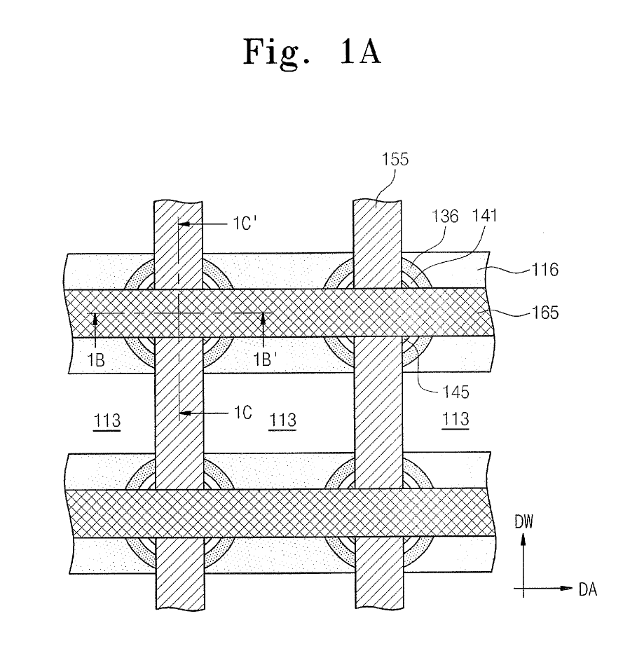

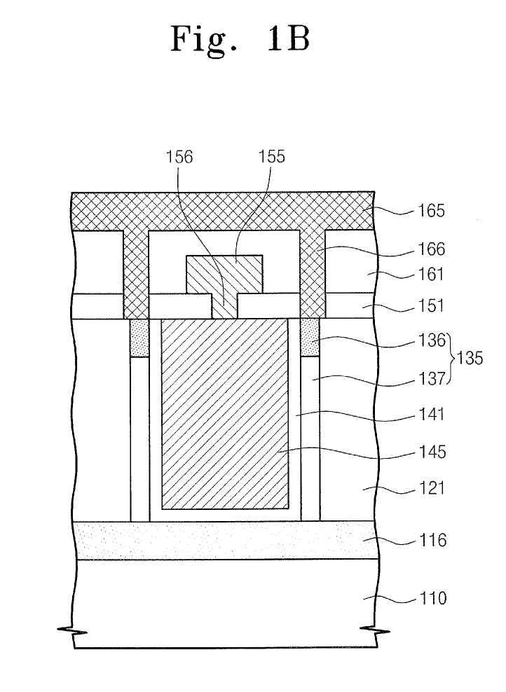

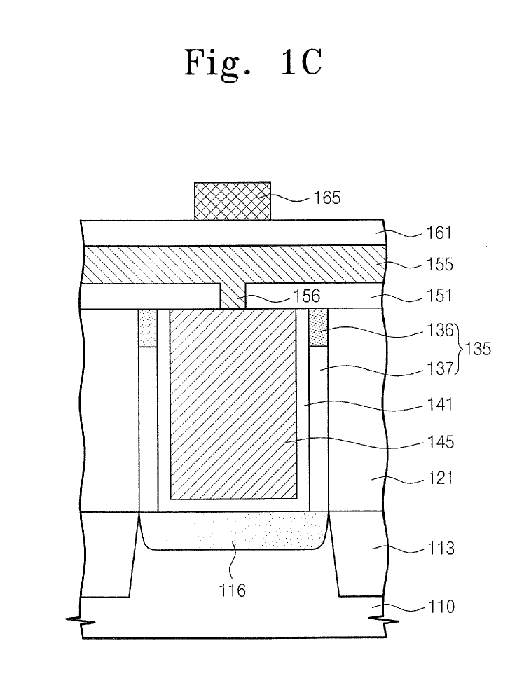

Referring to FIGS. 1A to 1C, a semiconductor device is illustrated according to an embodiment of the present invention. A device isolation layer 113 is disposed in a substrate 110 to define an active region. The substrate 110 may be a single crystalline substrate. The active region may extend to a first direction DA. A first impurity region 116 is formed in the active region. The first impurity region 116 corresponds to the active region and may be a line type extending to the first direction DA. A gate electrode 145 is formed on the first impurity region 116. The gate electrode may be a cylinder type. The gate electrode 145 may be doped polysilicon and/or metal. A gate insulating layer 141 surrounds a sidewall of the gate electrode 145. The gate insulating layer 141 may be interposed between the gate electrode 145 and the first impurity region 116. For instance, the gate insulating layer 141 may be a cup type layer surrounding the sidewall and a bottom surface of the gate electrode 145. The gate insulating layer 141 may be a silicon oxide layer. A single crystalline silicon pattern 135 surrounds an outer sidewall of the gate insulating layer 141. The single crystalline silicon pattern 135 may have the same crystallization structure as the substrate 110. The single crystalline silicon pattern 135 may include a second impurity region 136 and a channel region 137 thereunder. The top surfaces of the gate electrode 145, the gate insulating layer 141 and the single crystalline silicon pattern 135 may have substantially the same height. A first interlayer insulating layer 121 surrounds an outer sidewall of the single crystalline silicon pattern 135.

The gate electrode 145, the first impurity region 116, the second impurity region 136 and the channel region 137 may constitute a cell transistor of SOI (silicon on insulator) structure. The first impurity region 116 may be a source region and the second impurity region 136 may be a drain region. The first impurity region 116 may be a common source region of cell transistors arranged in the first direction DA. The first impurity region 116 may be grounded. The first impurity region 116 may be an island type and source regions of the cell transistors may be electrically separated from each other in another embodiment of the present invention.

A second interlayer insulating layer 151 is on the first insulating layer 121 including the SOI cell transistor. A word line 155 extending to a second direction DW is on the second interlayer insulating layer 151. The word line 155 is electrically connected to the gate electrode 145 through a contact 156 penetrating the second interlayer insulating layer 151. A third interlayer insulating layer 161 is on the second interlayer insulating layer 151. The third interlayer insulating layer 161 covers the word line 155. A bit line 165 is on the third interlayer insulating layer 161 to extend to the first direction DA. The bit line 165 is electrically connected to the second impurity region 136 through a contact 166 penetrating the second and third interlayer insulating layers 151, 161.

The channel region 137 can serve as a data storage element in the semiconductor device in accordance with the embodiments of the present invention. Since the channel region 137 is floated by the first and second impurity regions 116, 136, it becomes a floating body. Thus, data may be stored in the channel region 137 corresponding to the floating body using a floating body effect. If a high voltage is applied to the second impurity region 136 corresponding to the drain region, holes generated from the drain region due to ion impact ionization may not diffused into the substrate 110 and may diffused into the first impurity region 116 corresponding to the source region because the floating body is floated. The holes existing in the drain region are accumulated at the channel region 137 adjacent to the first impurity region 116. As a result, an electric potential of the channel region 137 increases and a threshold voltage decreases due to the increase of the electric potential. Therefore, when a specific gate voltage is applied to the gate electrode 145, an amount of a current flowing through the channel region 137 may become different by the holes accumulated on the channel region 137. The channel region 137 may be used as a data storage element using the amount of the current flowing through the channel region 137. For instance, the channel region 137 may be turned on before holes are accumulated in the channel region 137 and the channel region 137 may be turned off after holes are accumulated in the channel region 137. Thus, capacitors may not be required in the semiconductor device in accordance with the embodiment of the present invention. Also, a high integration memory device may be formed through a simple fabrication process.

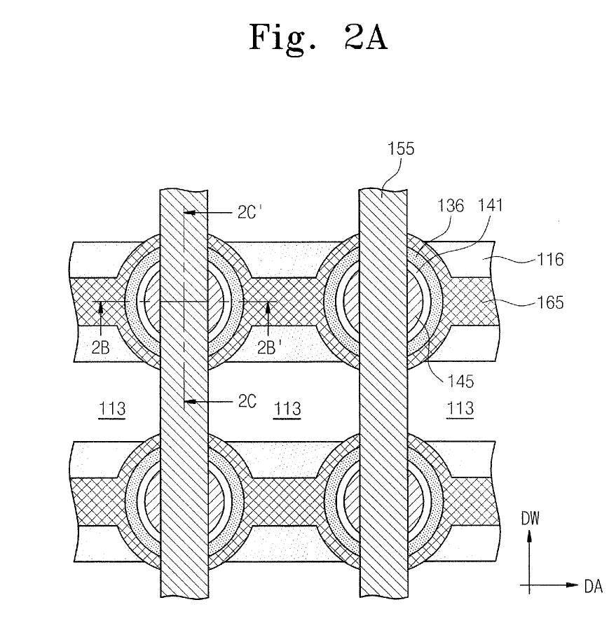

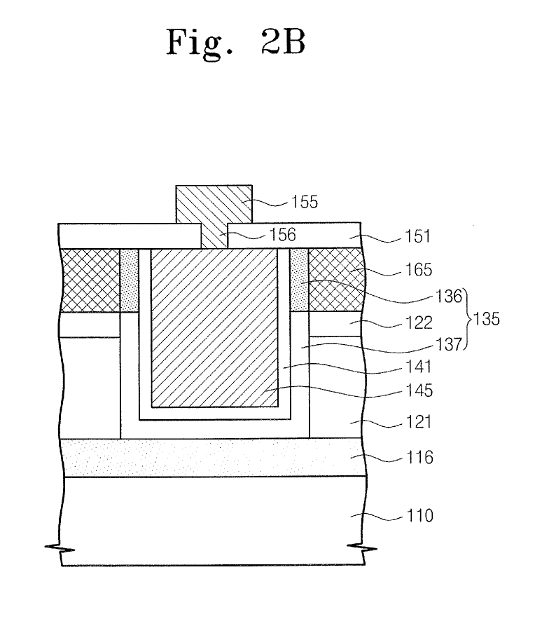

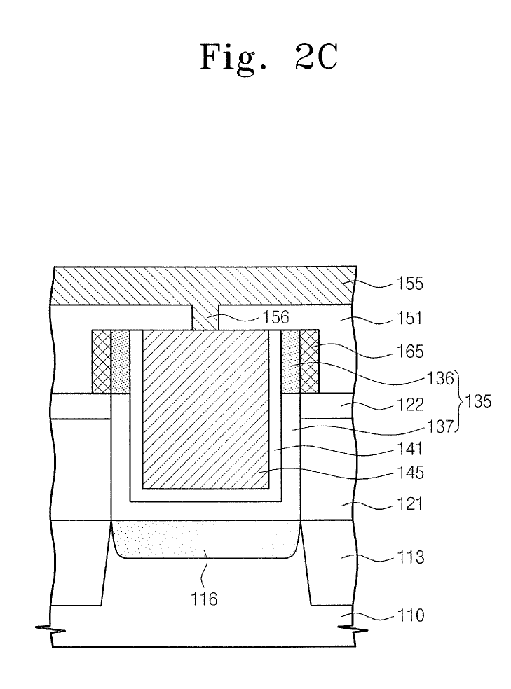

Referring to FIGS. 2A to 2C, a semiconductor device is illustrated according to another embodiment of the present invention. First and second interlayer insulating layers 121, 122 surround a channel region 137. A top surface of the second interlayer insulating layer 122 may have substantially the same height as that of the channel region 137. The first and second interlayer insulating layers 121, 122 may include material having an etching selectivity from each other. For instance, the first interlayer insulating layer 121 may be a silicon oxide layer and the second interlayer insulating layer 122 may be a silicon nitride layer. The semiconductor device may not include the second interlayer insulating layer 122 and the first interlayer insulating layer 121 may surround the channel region 137 in another embodiment of the present invention.

A bit line 165 may surround a second impurity region 136. Since the bit line 165 is directly in contact with the second impurity region 136, electric resistance may be reduced. Thus, an operation speed of the semiconductor device may increase. A third interlayer insulating layer 151 is on the second interlayer insulating layer 122 to cover the bit line 165. A word line 155 is on the third interlayer insulating layer 151. The word line 155 is electrically connected to a gate electrode 145 through the contact 156 penetrating the third interlayer insulating layer 151.

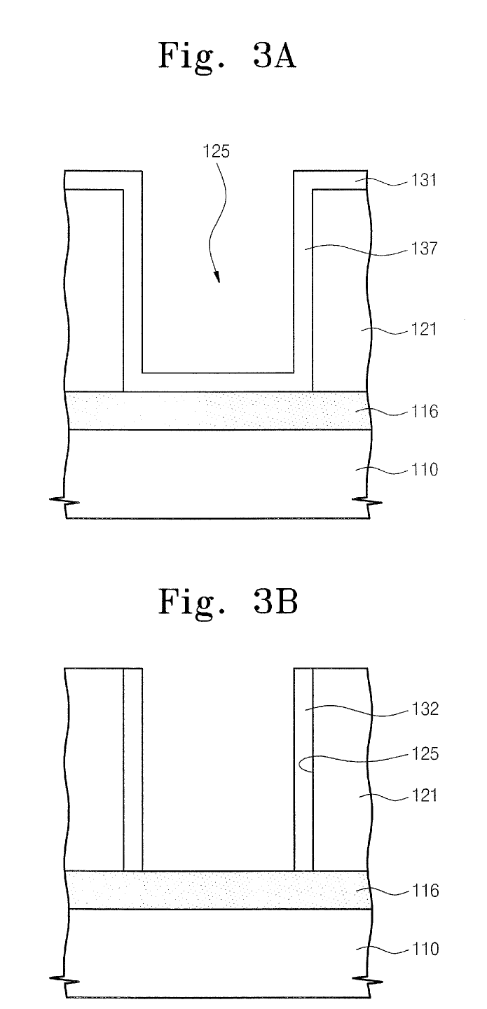

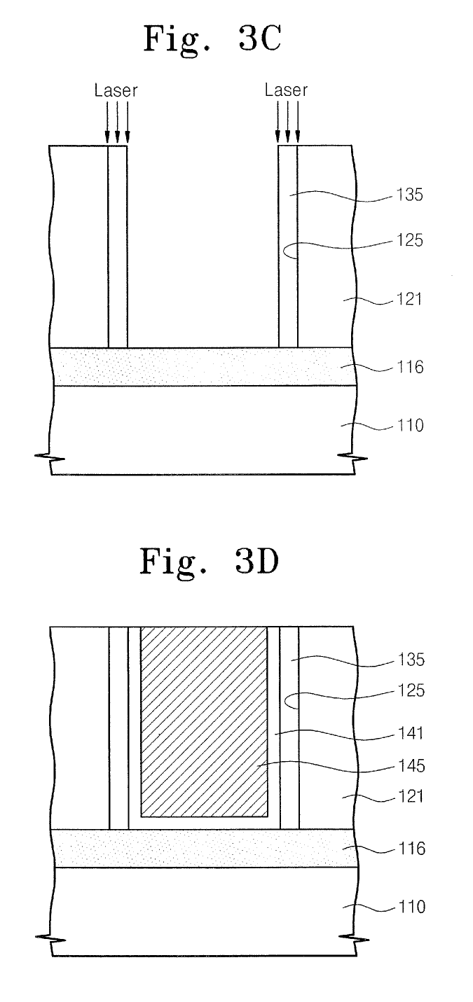

Referring to FIGS. 1A and 3A to 3F, a method of forming a semiconductor device is illustrated according to another embodiment of the present invention. Referring to FIGS. 1A and 3A, a device isolation layer 113 is formed at a substrate 110 to define an active region. The active region may extend to a first direction DA. A first impurity region 116 is formed in the active region by performing an ion implantation process. The first impurity region 116 may extend to the first direction DA to correspond to the active region. The first impurity region 116 may be formed to have a line-shaped configuration. The first impurity region 116 may be formed to have an island-shaped configuration in another embodiment of the present invention.

A first interlayer insulating layer 121 is formed on the substrate 110. The first interlayer insulating layer 121 is patterned to form an opening 125 exposing the first impurity region 116. The opening 125 may be formed to have a cylinder-shaped configuration. A silicon layer 131 is formed along a top surface of the first interlayer insulating layer 121, a sidewall of the first interlayer insulating layer 121 defining the opening 125 and an exposed top surface of the first impurity region 116. The silicon layer 131 may be formed of amorphous silicon or polysilicon. The silicon layer 131 may be formed to a thickness of 30 nanometers or less.

Referring to FIGS. 1A and 3B, a silicon pattern 132 is formed on the sidewall of the first interlayer insulating layer 121. The silicon pattern 132 may be formed by anisotropically etching the silicon layer 131. The top surface of the first interlayer insulating layer 121 and the top surface of the first impurity region 116 may be exposed. The silicon pattern 132 may have a tube-shaped configuration.

Referring to FIGS. 1A and 3C, a laser is irradiated into the silicon pattern 132 to form a single crystalline silicon pattern 135. The silicon pattern 132 is melted by the laser and is solidified again. A single-crystallization begins from a portion of the silicon pattern 132 being in contact with the substrate 110. Therefore, the single crystalline silicon pattern 135 may have the same crystalline structure as the substrate 110

Referring to FIGS. 1A and 3D, a gate insulating layer 141 is formed on the single-crystalline silicon pattern 135 in the opening 125. The gate insulating layer 141 may be formed to have a cup-shaped configuration along a sidewall of the single-crystalline silicon pattern 135 and the exposed top surface of the first impurity region 116. The gate insulating layer 141 may be formed by performing a thermal oxidation process.

A gate electrode 145 is formed in the opening 125 where the gate insulating layer 141 is formed. A conductive layer is formed in the opening 125 and on the top surfaces of the gate insulating layer 141 and the single-crystalline silicon pattern 135. And then the gate electrode 145 is formed by performing a planarization process exposing the single-crystalline silicon pattern 135. As a result, the top surfaces of the gate electrode 145, the gate insulating layer 141, and the single crystalline silicon pattern 135 may have substantially same height. The gate electrode 145 may be formed of doped polysilicon and/or metal. The gate electrode 145 may have a cylinder-shaped configuration.

Referring to FIGS. 1A and 3E, an ion implantation process is performed to form a second impurity region 136 in an upper portion of the single-crystalline silicon pattern 135. The single-crystalline silicon pattern 135 under the second impurity region 136 becomes a channel region 137. Thereby a vertical cell transistor having an SOI structure including the gate electrode 145, the source region 116 and the drain region 136 is formed. The source region 116 may be a common source region, which is connected to a source region of an adjacent transistor (not shown). The source region 116 may be grounded.

Referring to FIGS. 1A and 3F, a second interlayer insulating layer 151 may be formed on the substrate 110 including the vertical transistor. A contact 156 is formed on the gate electrode 145 to penetrate the second interlayer insulating layer 151. A word line 155 is formed on the second interlayer insulating layer 151 to be electrically connected to the contact 156 and extend to a second direction DW. The word line 155 is electrically connected to the gate electrode 145 through the contact 156.

A third interlayer insulating layer 161 is formed on the substrate 110 including the word line 155. A contact 166 is formed on the second impurity region 136 to penetrate the second and third interlayer insulating layers 151, 161. A bit line 165 is formed on the third interlayer insulating layer 161 to be electrically connected to the contact 166 and extend to the first direction DA. The bit line 165 is connected to the second impurity region 136 through the contact 166.

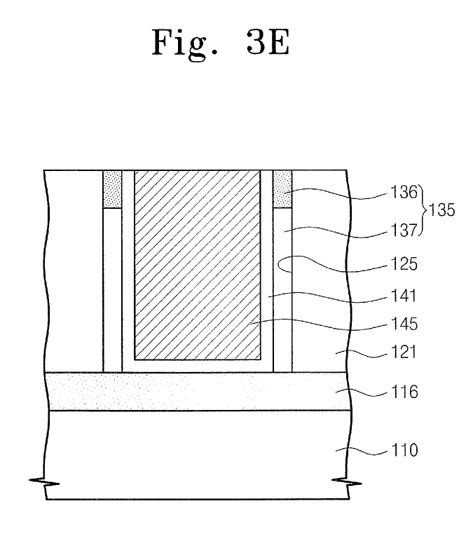

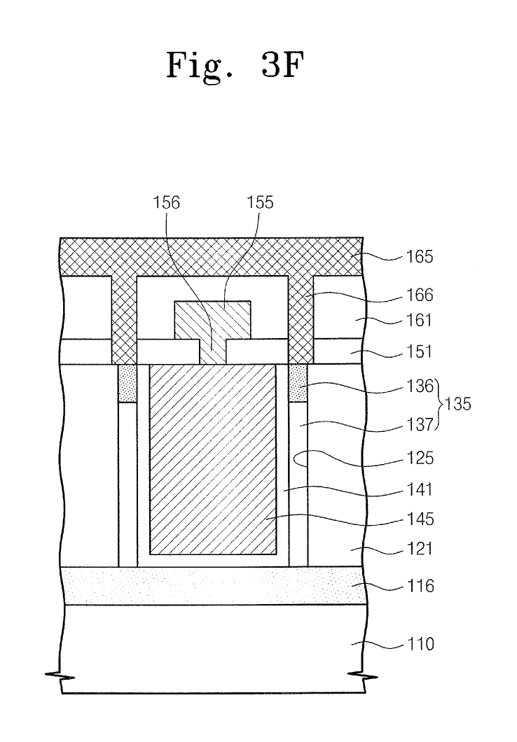

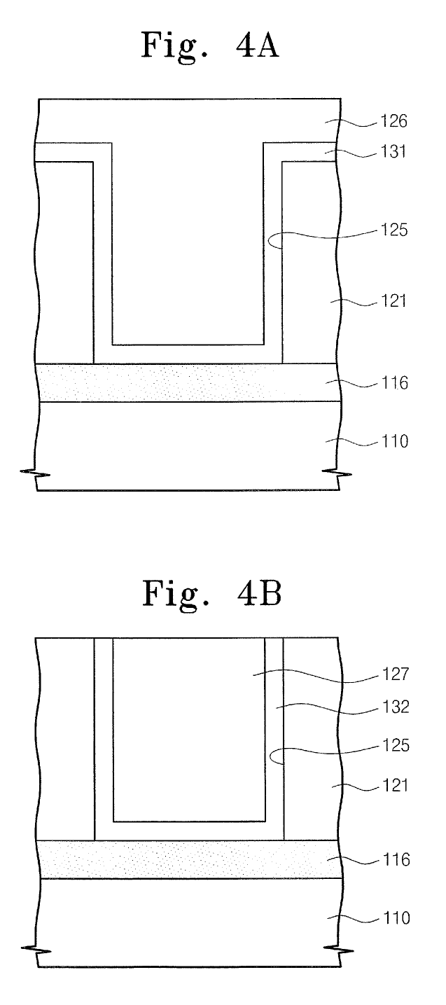

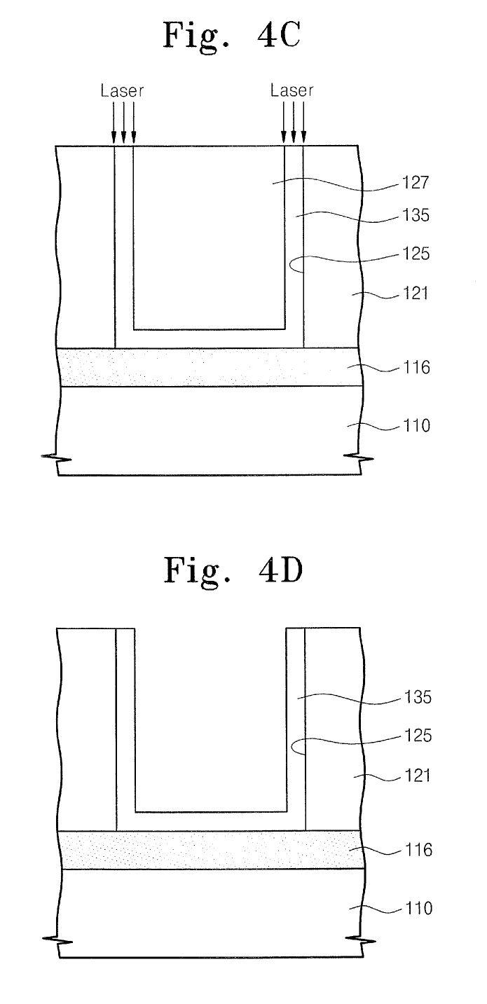

Referring to FIGS. 1A and 4A to 4D, a method of forming a semiconductor device is illustrated according to another embodiment of the present invention. Referring to FIGS. 1A and 4A, a sacrificial layer 126 is formed on a substrate 110 including the silicon layer 131 of FIG. 3A to fill the opening 125. The sacrificial layer 126 may be formed of material having an etching selectivity with respect to the first interlayer insulating layer 121. Referring to FIGS. 1A and 4B, a planarization process is performed to expose the first interlayer insulating layer 121 and to form a sacrificial layer pattern 127 in the opening 125. A silicon pattern 132 is formed between the sacrificial layer pattern 127 and the first interlayer insulating layer 121, and between the sacrificial layer pattern 127 and a first impurity region 116. That is, the silicon pattern 132 may be formed to have a cup-shaped configuration along a sidewall of the first interlayer insulating layer 121 defining the opening 125 and a top surface of the first impurity region 116 exposed by the opening 125.

Referring to FIGS. 1A and 4C, a laser is irradiated into the silicon pattern 132 to form a single-crystalline silicon pattern 135. The silicon pattern 132 is melted by the laser and is solidified again. A single-crystallization begins from a portion of the silicon pattern 132 being in contact with the substrate 110. Therefore, the single crystalline silicon pattern 135 may have the same crystalline structure as the substrate 110. Referring to FIGS. 1A and 4D, an etching process is performed to remove the sacrificial layer pattern 127. In the above etching process, a wet etching process may be used to selectively etch the sacrificial layer pattern 127. The process thereafter may be equal to the process illustrated in FIGS. 3C to 3F.

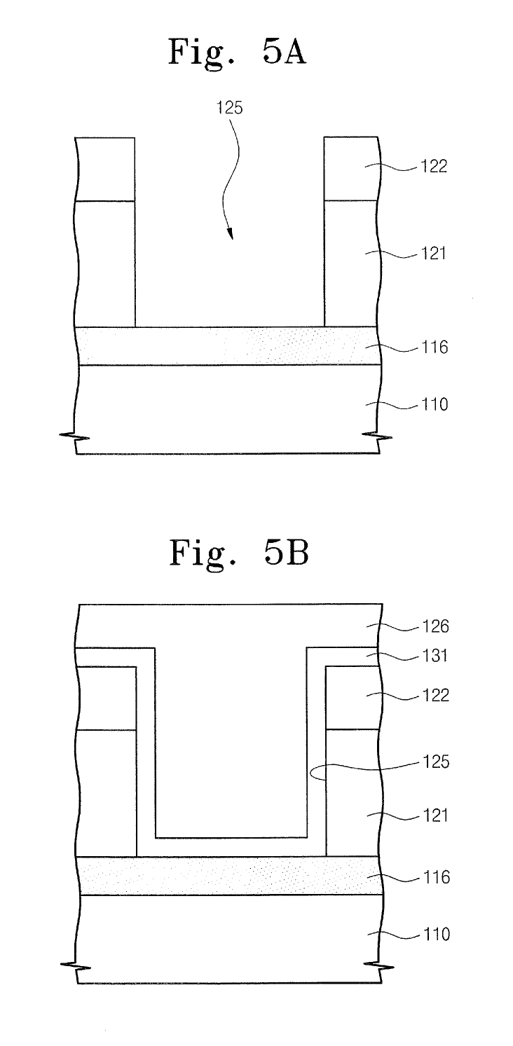

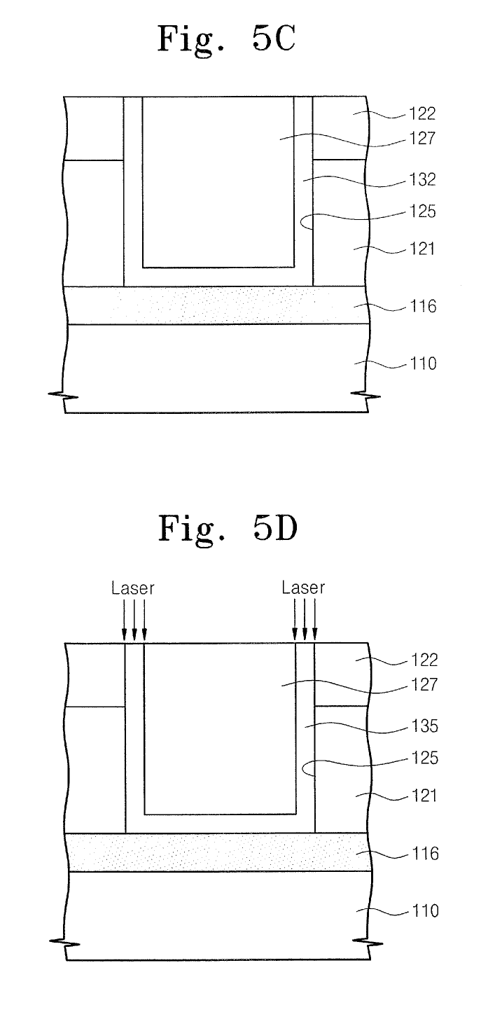

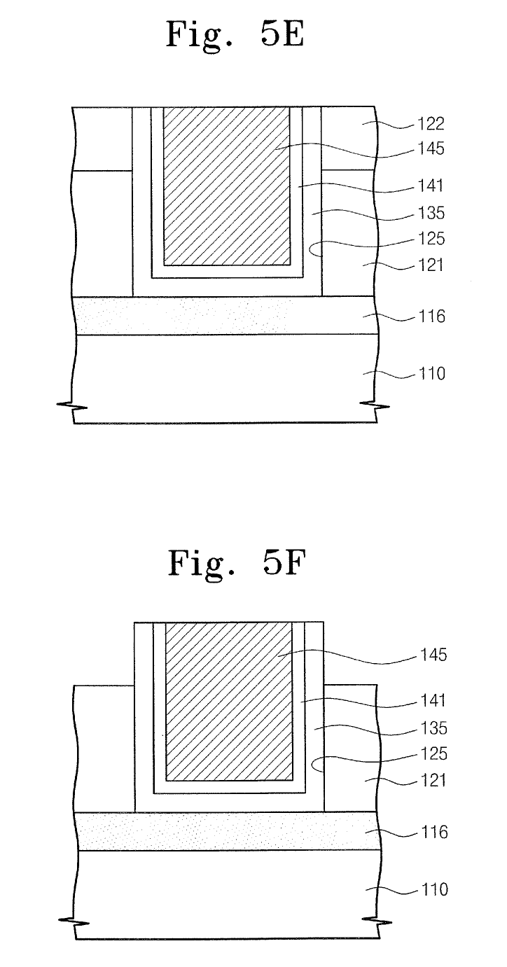

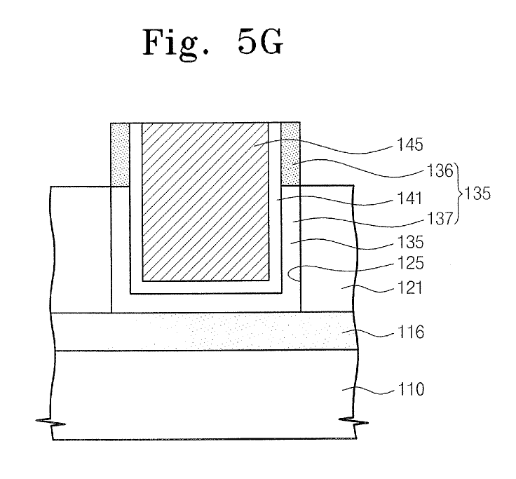

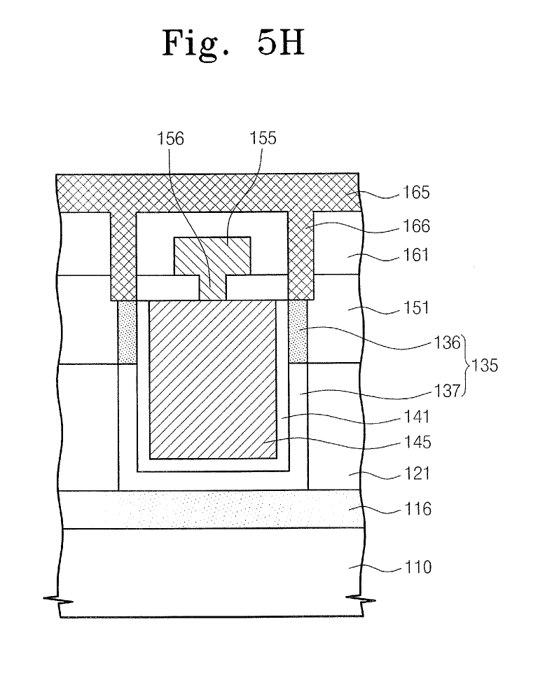

Referring to FIGS. 1A and 5A to 5H, a method of forming a semiconductor device is illustrated according to another embodiment of the present invention. Referring to FIGS. 1A and 5A, a first interlayer insulating layer 121 and a second interlayer insulating layer 122 are formed on a substrate 110. The first and second interlayer insulating layers 121, 122 may be formed of a material having an etching selectivity from each other. For instance, the first interlayer insulating layer 121 may be formed of silicon oxide layer and the second interlayer insulating layer 122 may be formed of silicon nitride layer. The first and second interlayer insulating layers 121, 122 are patterned to form an opening 125 exposing a first impurity region 116. The opening 125 may be formed to have a cylinder-shaped configuration.

Referring to FIGS. 1A and 5B, a silicon layer 131 is formed along a top surface of the second interlayer insulating layer 122, sidewalls of the first and second interlayer insulating layers 121, 122, and a top surface of the exposed first impurity region 116. A silicon layer 131 may be formed of amorphous or polysilicon. The silicon layer 131 may be formed to a thickness of 30 nanometers or less. A sacrificial layer 126 is formed on the substrate 110 including the silicon layer 131 to fill the opening 125. The sacrificial layer 126 may be formed of material having an etching selectivity with respect to the second interlayer insulating layer 122. For instance, the sacrificial layer 126 may be formed of silicon oxide layer.

Referring to FIGS. 1A and 5C, a planarization process is performed to expose the second interlayer insulating layer 122 and to form a sacrificial layer pattern 127 in the opening 125. A silicon pattern 132 is formed between the sacrificial layer pattern 127 and the first and second interlayer insulating layers 121, 122, and between the sacrificial layer pattern 127 and the first impurity region 116. That is, the silicon pattern 132 may be formed to have a cup-shaped configuration along the sidewalls of the first and second interlayer insulating layers 121, 122 defining the opening 125, and a top surface of the first impurity region 116 exposed by the opening 125.

Referring to FIGS. 1A and 5D, a laser is irradiated onto the silicon pattern 132 to form a single crystalline silicon pattern 135. The silicon pattern 132 is melted by the laser and is solidified again. A single crystallization begins from a portion of the silicon pattern 132 being in contact with the substrate 110. Therefore, the single crystalline silicon pattern 135 may have the same crystalline structure as the substrate 110.

Referring to FIGS. 1A and 5E, an etching process is performed to remove the sacrificial layer pattern 127. In the above etching process, a wet etching process may be used to selectively etch the sacrificial layer pattern 127. For instance, hydrofluoric (HF) acid may be used as an etching solution in the above wet etching process. A gate insulating layer 141 is formed on the single crystalline silicon pattern 135 in the opening 125. The gate insulating layer 141 may be formed to have a cup-shaped configuration along an inside of the single crystalline silicon pattern 135 exposed by the opening 125. The gate insulating layer 141 may be formed by means of a thermal oxidation process.

A gate electrode 145 is formed in the opening 125 where the gate insulating layer 141 is formed. A conductive layer is formed in the opening 125 and on the top surfaces of the gate insulating layer 141 and the single crystalline silicon pattern 135. And then a planarization process is performed to form the gate electrode 145. As a result, the top surfaces of the gate electrode 145, the gate insulating layer 141, and the single crystalline silicon pattern 135 may be located at the same level. The gate electrode 145 may be formed of doped polysilicon and/or metal. The gate electrode 145 may be formed to have a cylinder-shaped configuration.

Referring to FIGS. 1A and 5F, an etching process is performed to remove the second interlayer insulating layer 122. In the above etching process, a wet etching process may be used to selectively etch the second interlayer insulating layer 122. For instance, phosphorus acid solution may be used as an etching solution in the above wet etching process. Due to the above etching process, a top sidewall of the single crystalline silicon pattern 135 is exposed.

Referring to FIGS. 1A and 5G, an ion implantation process is performed to form a second impurity region 136 on the exposed single crystalline silicon pattern 135. The single crystalline silicon pattern 135 under the second impurity region 136 becomes a channel region 137. A top surface of the channel region 137 may be substantially even with the top surface of the first interlayer insulating layer 121. That is, the height of the top surface of the channel region 137 may be controlled by controlling the thickness of the forming first and second interlayer insulating layers 121, 122. As a result, SOI cell transistor is formed to include the gate electrode 145, the source region 116, and the drain region 136.

Referring to FIGS. 1A and 5H, a third interlayer insulating layer 151 is formed on the substrate 110 including the cell transistor. The third interlayer insulating layer 151 covers the sidewall of the second impurity region 136. A contact 156 is formed on the gate electrode 145 to penetrate the third interlayer insulating layer 151. A word line 155 is formed on the third interlayer insulating layer 151 to be electrically connected to the contact 156 and extend to a second direction DW. The word line 155 is electrically connected to the gate electrode 145 through the contact 156.

A fourth interlayer insulating layer 161 is formed on the substrate 110 including the word line 155. A contact 166 is formed on the second impurity region 136 to penetrate the third and fourth interlayer insulating layers 151, 161. A bit line 165 is formed on the fourth interlayer insulating layer 161 to be electrically connected to the contact 166 and extend to a first direction DA. The bit line 165 is electrically connected to the second impurity region 136 through the contact 166.

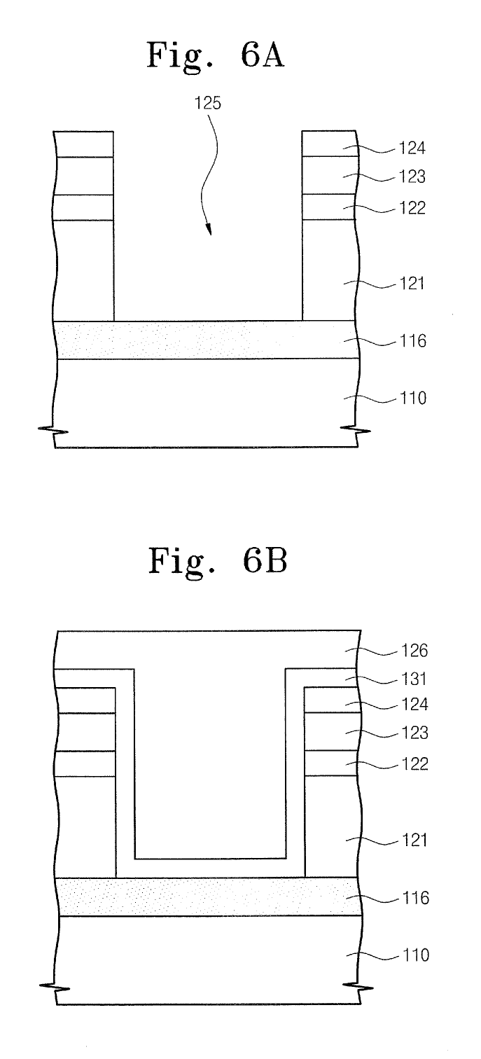

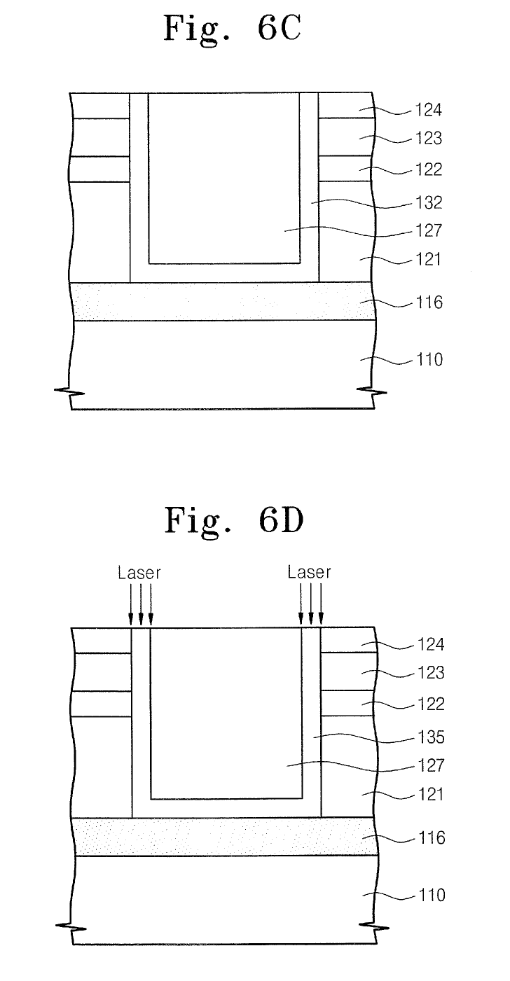

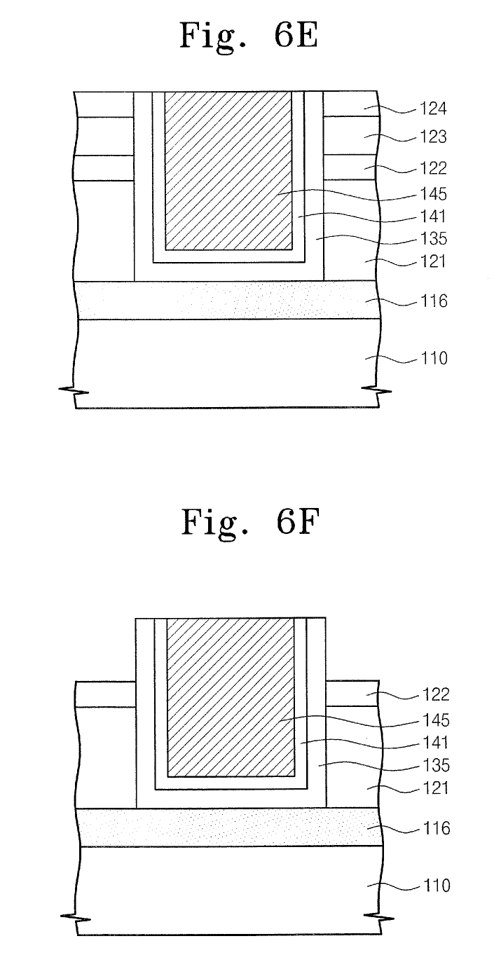

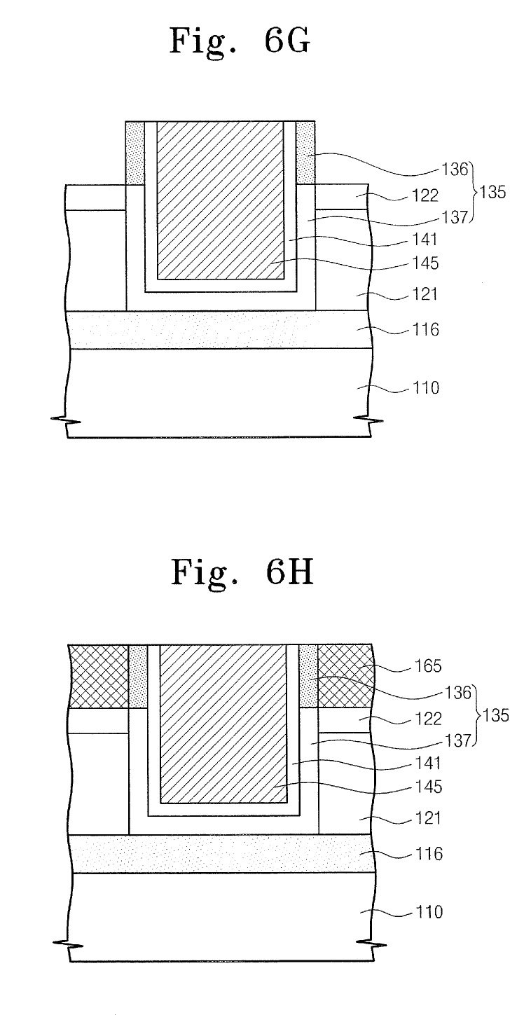

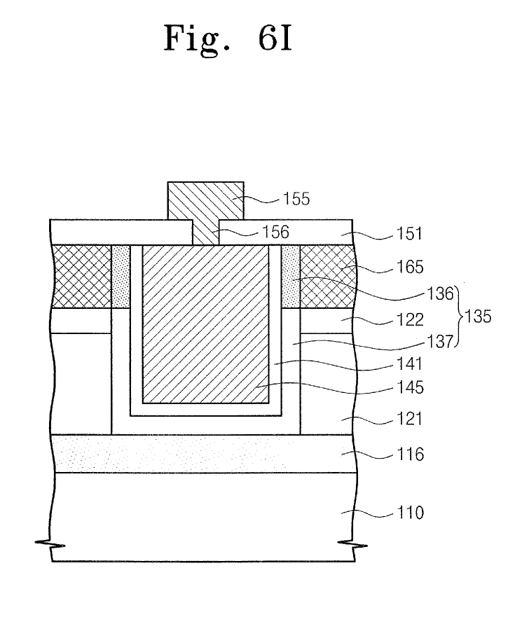

Referring to FIGS. 2A and 6A to 6I, a method of forming a semiconductor device is illustrated according to another embodiment of the present invention. Referring to FIGS. 1A and 6A, first to fourth interlayer insulating layers 121, 122, 123, 124 are formed on the substrate 110. At least one layer of the first to fourth interlayer insulating layers 121, 122, 123, 124 may be formed of a material having an etching selectivity with respect to its overlying layer and/or underlying layer. For instance, the second interlayer insulating layer 122 may be formed of material having an etching selectivity with respect to the first interlayer insulating layer 121 and/or the third interlayer insulating layer 123, and the third interlayer insulating layer 123 may be formed of material having an etching selectivity with respect to the second interlayer insulating layer 122 and/or the fourth interlayer insulating layer 124. For instance, the first and third interlayer insulating layers 121, 123 may be formed of silicon oxide layer and the second and fourth interlayer insulating layers 122, 124 may be formed of silicon nitride layer. The first to fourth interlayer insulating layers 121, 122, 123, 124 are patterned to form an opening 125 exposing a first impurity region 116. The opening 125 may be formed to have a cylinder-shaped configuration.

Referring to FIGS. 2A and 6B, a silicon layer 131 is formed along a top surface of the fourth interlayer insulating layer 124, sidewalls of the first to fourth interlayer insulating layers 121, 122, 123, 124 defining the opening 125, and a top surface of the exposed first impurity region 116. The silicon layer 131 may be formed of amorphous silicon or polysilicon. The silicon layer 131 may be formed to a thickness of 30 nanometers or less.

A sacrificial layer 126 is formed on the substrate 110 including the silicon layer 131 to fill the opening 125. The sacrificial layer 126 may be formed of material having an etching selectivity with respect to the fourth interlayer insulating layer 124. For instance, the sacrificial layer 126 may be formed as a silicon oxide layer.

Referring to FIGS. 2A and 6C, a planarization process is performed to expose the fourth interlayer insulating layer 124 and to form a sacrificial layer pattern 127 in the opening 125. A silicon pattern 132 is formed between the sacrificial layer pattern 127 and the first to fourth interlayer insulating layers 121, 122, 123, 124, and between the sacrificial layer pattern 127 and the first impurity region 116. That is, the silicon pattern 132 may be formed to have a cup-shaped configuration along the sidewalls of the first to fourth interlayer insulating layers 121, 122, 123, 124 defining the opening 125, and the top surface of the first impurity region 116 exposed by the opening 125.

Referring to FIGS. 2A and 6D, a laser is irradiated onto the silicon pattern 132 to form a single crystalline silicon pattern 135. The silicon pattern 132 is melted by the laser and is solidified again. A single crystallization begins from a portion of the silicon pattern 132 being in contact with the substrate 110. Therefore, the single crystalline silicon pattern 135 may have the same crystalline structure as the substrate 110.

Referring to FIGS. 2A and 6E, an etching process is performed to remove the sacrificial layer pattern 127. In the above etching process, a wet etching process may be used to selectively etch the sacrificial layer pattern 127. For instance, hydrofluoric (HF) acid may be used as an etching solution in the above wet etching process.

A gate insulating layer 141 is formed on the single crystalline silicon pattern 135 in the opening 125. The gate insulating layer 141 may be formed to have a cup-shaped configuration along the inside of the single crystalline silicon pattern 135 exposed by the opening 125. The gate insulating layer 141 may be formed by means of a thermal oxidation process.

A gate electrode 145 is formed in the opening 125 where the gate insulating layer 141 is formed. A conductive layer is formed in the opening 125 and on the top surfaces of the gate insulating layer 141 and the single crystalline silicon pattern 135. And then a planarization process is performed to form the gate electrode 145. As a result, the top surfaces of the gate electrode 145, the gate insulating layer 141, and the single crystalline silicon pattern 135 may be located at the same level. The gate electrode 145 may be formed of doped polysilicon and/or metal. The gate electrode 145 may be formed to have a cylinder-shaped configuration.

Referring to FIGS. 2A and 6F, an etching process is performed to remove the third and fourth interlayer insulating layers 123, 124. In the above etching process, a wet etching process may be used to selectively etch the third and fourth interlayer insulating layers 123, 124. Due to the above etching process, the top sidewall of the single crystalline silicon pattern 135 is exposed. In another embodiment of the present invention, only the fourth interlayer insulating layer 124 may be etched or the second to fourth interlayer insulating layers 122, 123, 124 may be etched.

Referring to FIGS. 2A and 6G, an ion implantation process is performed to form a second impurity region 136 on the exposed single crystalline silicon pattern 135. The single crystalline silicon pattern 135 under the second impurity region 136 becomes a channel region 137. The top surface of the channel region 137 may be substantially even with the top surface of the second interlayer insulating layer 122. That is, the height of the top surface of the channel region 137 may be controlled by controlling the thickness of the forming first to fourth interlayer insulating layers 121, 122, 123, 124, or the number of removing layers. As a result, a silicon on insulator (SOI) cell transistor is formed including the gate electrode 145, the source region 116, and the drain region 136.

Referring to FIGS. 2A and 6H, a bit line 165 is formed on the second interlayer insulating layer 122 to surround the second impurity region 136 and extend to a first direction DA. A conductive layer is formed on the second interlayer insulating layer 122, and then an etching process is performed to form the bit line 165. The etching process may include a planarization process. The bit line 165 may be formed to a thickness substantially equal to the second impurity region 136. The bit line 165 is directly in contact with the second impurity region 136 not through a contact. Thus, the resistance between the bit line 165 and the second impurity region 136 may be reduced.

Referring to FIGS. 2A and 6I, a fifth interlayer insulating layer 151 is formed on the substrate 110 including the bit line 165. The fifth interlayer insulating layer 151 covers a sidewall of the bit line 165 (refer to FIG. 2C). A contact 156 is formed on the gate electrode 145 to penetrate the fifth interlayer insulating layer 151. A word line 155 is formed on the fifth interlayer insulating layer 151 to be electrically connected to the contact 156 and extend to a second direction DW. The gate electrode 145 is electrically connected to the word line 155 through the contact 156.

Accordingly, as described above, the memory cell transistor of FIG. 2C includes a semiconductor substrate 110 having a first impurity region 116 of first conductivity type (e.g., N-type) therein. A U-shaped semiconductor layer 135 having a second impurity region 136 of first conductivity type therein is also provided on the first impurity region 116. A gate insulating layer 141 is provided, which lines a bottom and an inner sidewall of the U-shaped semiconductor layer 135. A gate electrode 145 is provided on the gate insulating layer 141. The gate electrode 145 is surrounded by the inner sidewall of the U-shaped semiconductor layer 135. A word line 155 is provided, which is electrically coupled to the gate electrode 145, and a bit line 165 is provided, which is electrically coupled to the second impurity region 136. The U-shaped semiconductor layer, which may be a monocrystalline silicon region, includes a U-shaped channel region 137 that functions as a data storage region within the transistor. The second impurity region 136 may also be a ring-shaped drain region of the transistor. Furthermore, the first impurity region 116 may function as a source region of the transistor, which electrically contacts a bottom of the U-shaped channel region 137. The bit line 165 may also include a ring-shaped metal region that surrounds and contacts the ring-shaped drain region 136.

The memory cell transistor of FIG. 1B includes a semiconductor substrate 110, which has a first impurity region 116 of first conductivity type therein that functions as a source region of the memory cell transistor. A cylinder-shaped gate electrode 145 is provided on the first impurity region 116 and a U-shaped gate insulating layer 141 is provided on the first impurity region 116. This insulating layer 141 lines a bottom and sidewall of the cylinder-shaped gate electrode 145. A ring-shaped semiconductor layer 135 is also provided, which surrounds the U-shaped gate insulating layer 141. The ring-shaped semiconductor layer 135 has a first end electrically connected to the first impurity region 116 and a second end that includes a drain region 136 of the transistor. A word line 155 is provided, which is electrically coupled to the gate electrode 145, and a bit line 165 is provided, which is electrically coupled to the second impurity region 136.

In the drawings and specification, there have been disclosed typical preferred embodiments of the invention and, although specific terms are employed, they are used in a generic and descriptive sense only and not for purposes of limitation, the scope of the invention being set forth in the following claims.

1. A memory cell transistor, comprising:
a semiconductor substrate having a first impurity region of first conductivity type therein;
a U-shaped semiconductor layer having a second impurity region of first conductivity type therein, on the first impurity region;
a gate insulating layer lining a bottom and an inner sidewall of said U-shaped semiconductor layer;
a gate electrode on said gate insulating layer, said gate electrode surrounded by the inner sidewall of the U-shaped semiconductor layer;
a word line electrically coupled to said gate electrode; and
a bit line electrically coupled to the second impurity region.

2. The transistor of claim 1, wherein said U-shaped semiconductor layer comprises monocrystalline silicon.

3. The transistor of claim 1, wherein said U-shaped semiconductor layer comprises a U-shaped channel region that functions as a data storage region within the transistor; and wherein the second impurity region is a ring-shaped drain region of the transistor.

4. The transistor of claim 3, wherein the first impurity region functions as a source region of the transistor that electrically contacts a bottom of the U-shaped channel region.

5. The transistor of claim 3, wherein said bit line comprises a ring-shaped metal region that surrounds and contacts the ring-shaped drain region.

6. A memory cell transistor, comprising:
a semiconductor substrate having a first impurity region of first conductivity type therein;
a cylinder-shaped gate electrode on the first impurity region;
a U-shaped gate insulating layer lining a bottom and sidewall of said cylinder-shaped gate electrode, on the first impurity region;
a ring-shaped semiconductor layer surrounding said U-shaped gate insulating layer, said ring-shaped semiconductor layer having a first end electrically connected to the first impurity region and a second end comprising a drain region of the transistor;
a word line electrically coupled to said gate electrode; and
a bit line electrically coupled to the second impurity region.

7. The transistor of claim 6, wherein said ring-shaped semiconductor layer comprises monocrystalline silicon.

8. The transistor of claim 7, wherein said ring-shaped semiconductor layer comprises a ring-shaped channel region that functions as a data storage region within the transistor.

9. The transistor of claim 8, wherein the first impurity region functions as a source region of the transistor.

10. A memory device comprising:
a substrate including a first impurity region;
a conductive pattern on the first impurity region;
a semiconductor pattern surrounding a sidewall of the conductive pattern and including a second impurity region in an upper part of the semiconductor pattern;
an insulating layer between the conductive pattern and the semiconductor pattern;
a first conductive line electrically connected to the conductive pattern; and
a second conductive line electrically connected to the second impurity region.

11. The device of claim 10, wherein the semiconductor pattern is a single crystalline silicon pattern.

12. The device of claim 10, wherein the semiconductor pattern includes a channel region between the first impurity region and the second impurity region.

13. The device of claim 12, wherein the channel region serves as a data storage element.

14. The device of claim 12, further comprising:
an interlayer insulating layer surrounding an outer wall of the semiconductor pattern and having a top surface as high as a top surface of the channel region.

15. The device of claim 14, wherein the interlayer insulating layer includes a first and second interlayer insulating layers having an etching selectivity from each other.

16. The device of claim 10, wherein a top surface of the semiconductor pattern has the same height as a top surface of the conductive pattern.

17. The device of claim 10, wherein the conductive pattern is cylinder-shaped.

18. The device of claim 10, wherein the insulating layer is interposed between the first impurity region and the conductive pattern.

19. The device of claim 10, wherein the first impurity region extends to a direction of the second conductive line.

20. The device of claim 10, wherein the second conductive line surrounds the second impurity region.

21. The device of claim 20, wherein the second conductive line has the same thickness as the second impurity region.

22.-34. (canceled)
